(19) United States
(12) Patent Application Publication
(10) Pub. No.: US 2008/0254650 A1
(43) Pub. Date: Oct. 16, 2008

(54) LIGHT-EMITTING DIODE AND METHOD FOR PRODUCING IT

(75) Inventors: Norikazu Kadotani, Hachioji-shi (JP); Atsushi Nishida, Mitaka-shi (JP); Koichi Fukasawa, Kofu-shi (JP); Hirohiko Ishii, Minamitsuru-gun (JP)

Correspondence Address: BROWDY AND NEIMARK, P.L.L.C.;624 NINTH STREET, NW, SUITE 300, WASHINGTON, DC, 20001-5303, US

(73) Assignee: CITIZEN ELECTRONICS CO., LTD., Fujiyoshida-shi (JP)

(21) Appl. No.: 12/059,473

(22) Filed: Mar. 31, 2008

(30) Foreign Application Priority Data
Mar. 29, 2007 (JP) 2007-087826

(51) Int. Cl. H05K 1/00; H05K 3/30

(52) U.S. Cl. 439/56; 29/832

(57) ABSTRACT

An LED includes a printed circuit board, at least one LED element including a junction and mounted on the printed circuit board, a first sealing member disposed to cover side surfaces of the LED element, and a second sealing member disposed to cover side surfaces of the LED element. The first sealing member is configured to reflect and shield light emitted from the junction of the LED element, and the second sealing member is configured to transmit light emitted from the LED element.

### CROSS-REFERENCE TO THE RELATED APPLICATION

This application is based on and claims priority from Japanese Patent Application No. 2007-087826, filed on Mar. 29, 2007, the disclosure of which is incorporated herein by reference in its entirety.

### BACKGROUND OF THE INVENTION

1. Field of the Invention

The present invention relates to a light-emitting diode (LED) and a method for producing such an LED.

2. Description of Related Art

For a conventional surface-mount-type LED, it has become more important to improve emission efficiency, to extend a life duration of an instrument using the LED, and to miniaturize the LED. There also has been a requirement for a method to produce an LED inexpensively.

FIGS. 17A and 17B illustrate conventional surface-mount type-LEDs, respectively.

The LED 100 shown in FIG. 17A includes a board 112 provided with a pair of electrodes 114 and 116, an LED element 106 mounted on, for example, the electrode 114 and a transparent sealing resin 110 provided on the board 112 to seal the LED element 106.

The LED element 106 includes anode and cathode electrodes 104, and a junction 108 which emits light when electricity is applied to the LED element 106.

Light 118 emitted in a lateral direction from the junction 108 of the LED element 106 travels in an almost straight line in the transparent sealing resin 110 as light 120, as shown by the arrow in FIG. 17A.

With this structure, light is emitted from side surfaces and an upper surface of the transparent sealing resin 110, and therefore, even if one of the side surfaces and the upper surface is required to be as a light-emitting surface of the LED, light is emitted from other surfaces as well as the light-emitting surface. As a result, intensity of light emitted from the light-emitting surface is significantly reduced.

The LED 102 shown in FIG. 17B differs from the LED 100 in structure where a plurality of LED elements 122, 124 and 126 are mounted on an electrode 114 of a board 112.

In the LED 102, light 118 emitted laterally from a junction 108 of the LED element 122 travels in an almost straight line in a transparent sealing resin 110 as light 120 and then enters a side surface of the adjacent LED element 124 as light 128 to be absorbed therein.

In this way, if the plurality of LED elements are mounted and used, a part of laterally emitted light is absorbed in a side surface of the adjacent LED element, resulting in a decrease of light intensity due to absorbed light in side surfaces of adjacent LED elements.

### SUMMARY OF THE INVENTION

An object of the present invention is to provide an LED capable of achieving enhanced emission efficiency and miniaturization.

Another object of the present invention is to provide a method for inexpensive production of a downsized LED with high emission efficiency.

An LED according to one embodiment of the present invention includes a printed circuit board including at least a pair of electrodes, a plurality of LED elements each including a junction and mounted on the printed circuit board, and the LED elements electrically connected to the electrodes on the printed circuit board respectively, a first sealing member disposed to cover side surfaces of each of the LED elements and having substantially a same height as each of the LED elements, and a second sealing member disposed to cover a flat surface composed of the upper surfaces of the LED elements and the upper surface of the first sealing member.

Here, the first sealing member is configured to reflect and shield light laterally emitted from the junctions of the LED elements, and the second sealing member disposed above the junction is configured to transmit light emitted from the junctions of the LED elements. It is preferable that outlines of the first and the second sealing members are substantially same in a top plan view, for achieving a smaller LED with sufficiently enhanced light intensity.

A method for producing an LED according to one embodiment of the present invention includes a mounting process to mount a plurality of LED elements on a board aggregate, a first sealing member-forming process to form a first sealing member configured to cover side surfaces of each of the LED elements, shield and reflect light emitted laterally from junctions of the LED elements, a second sealing member-forming process to form a second sealing member with a light-transmitting property on a substantially flat surface composed of the upper surface of the first sealing member and the upper surfaces of the LED elements, and a cutting process to cut lengthwise and crosswise selectively, the board aggregate, the first sealing member and the second sealing member to form a plurality of LEDs each including a board, at least one LED element mounted on the board, a first sealing member disposed to cover side surfaces the LED element and a second sealing member disposed on a flat surface composed of the upper surfaces of the first sealing member and the LED element.

### BRIEF DESCRIPTION OF THE DRAWINGS

FIG. 1 is a plan view showing an LED according to a first embodiment of the present invention.

FIG. 2A is a sectional view taken along a line A-A in FIG. 1.

FIG. 2B is a sectional view taken along a line B-B in FIG. 1.

FIG. 3 is a perspective view showing an LED according to a first embodiment of the present invention.

FIG. 4 is a plan view showing an LED according to a second embodiment of the present invention.

FIG. 5A is a sectional view taken along a line A-A in FIG. 4.

FIG. 5B is a sectional view taken along a line B-B in FIG. 4.

FIG. 6 is a perspective view showing the LED according to the second embodiment of the present invention.

FIG. 7 is a plan view showing an LED according to a third embodiment of the present invention.

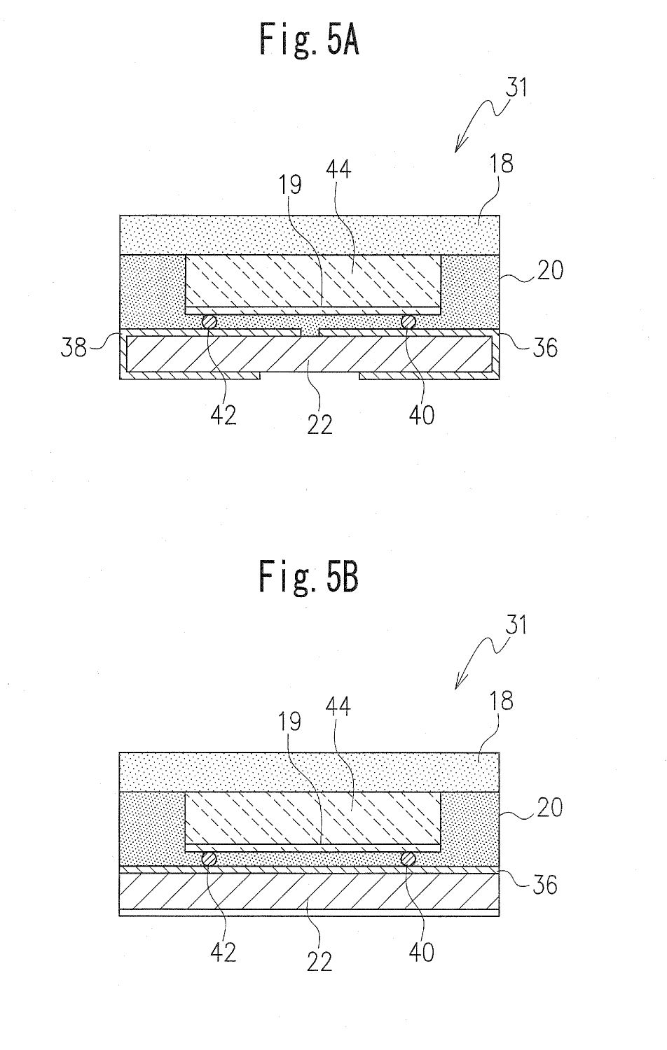

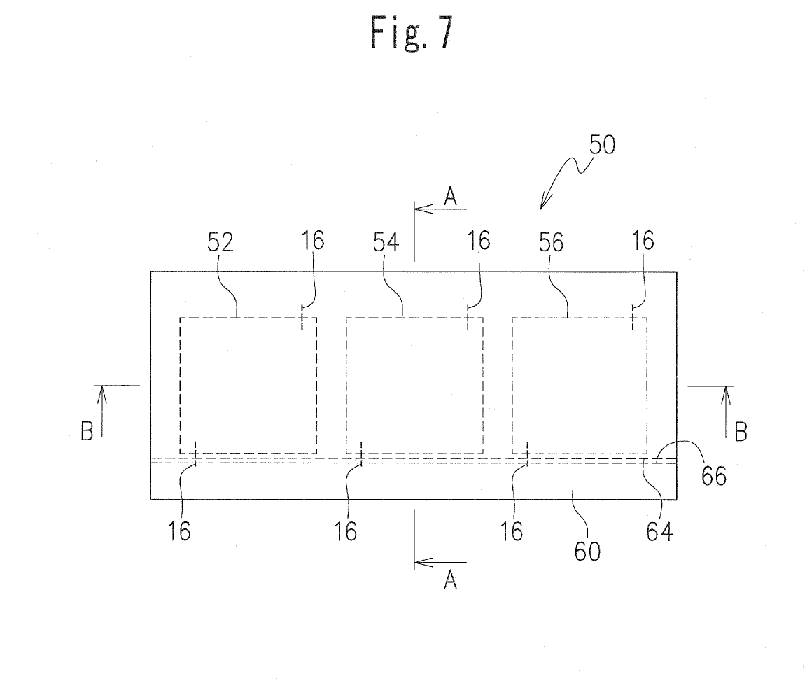

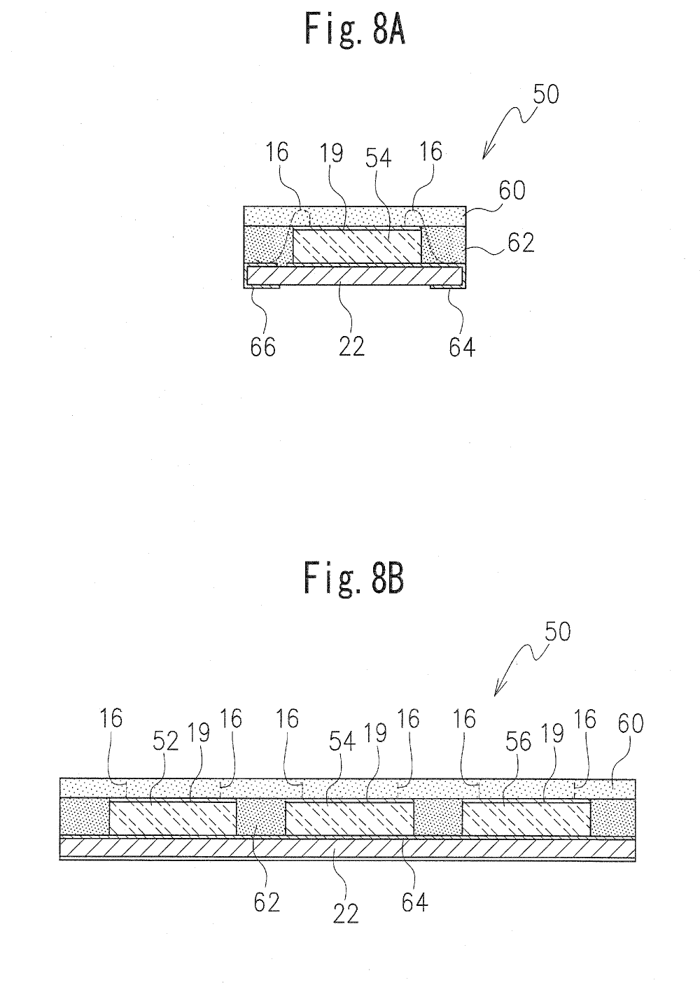

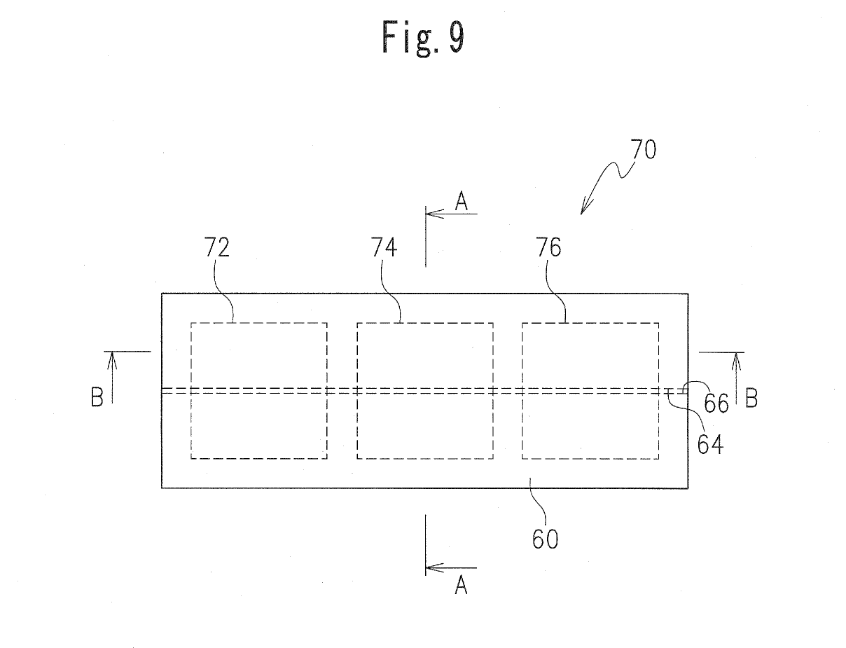

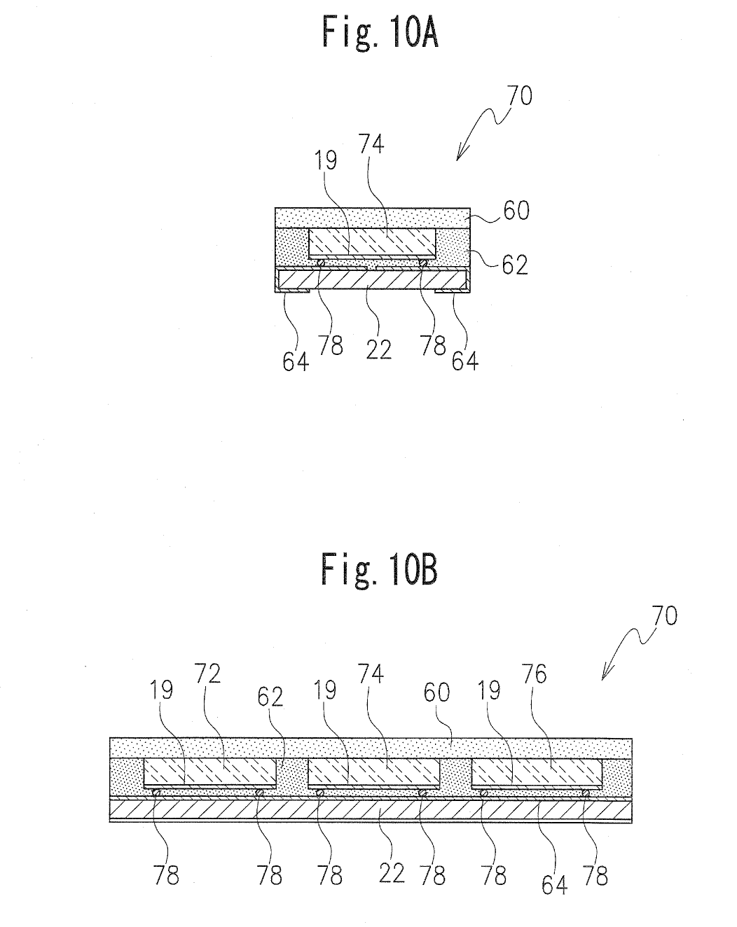

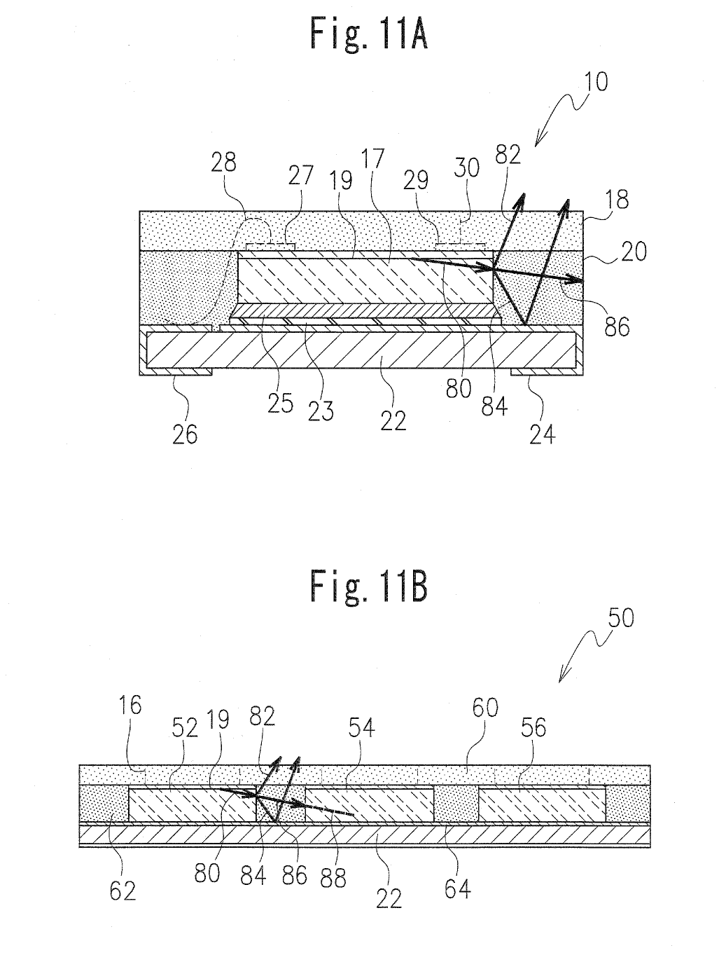

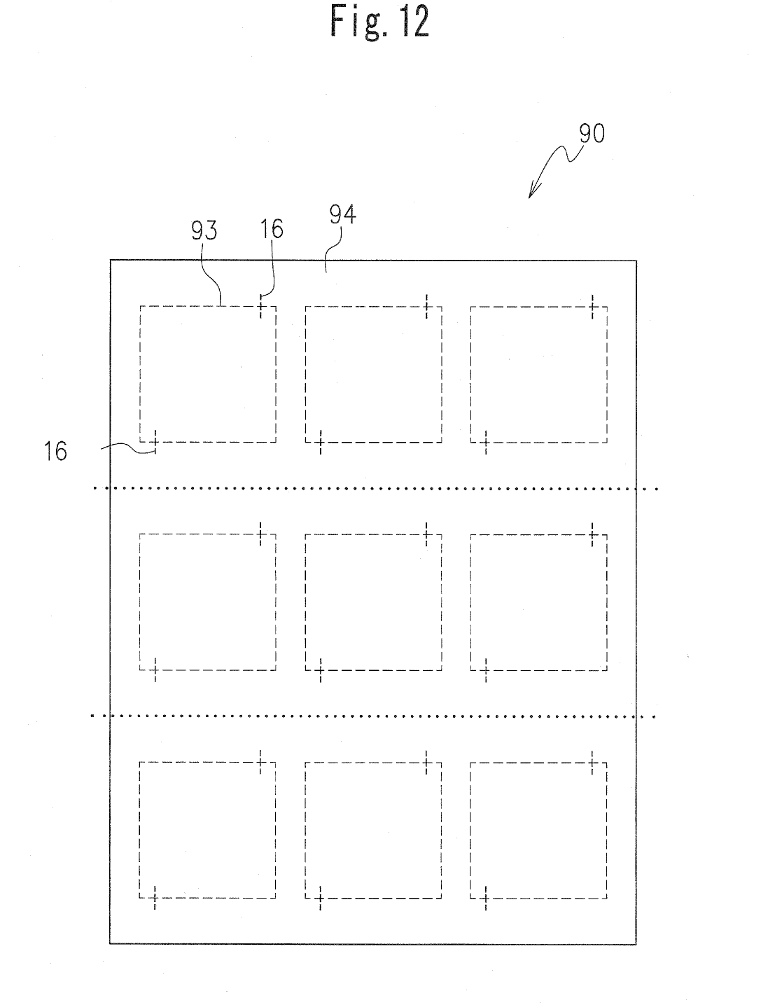

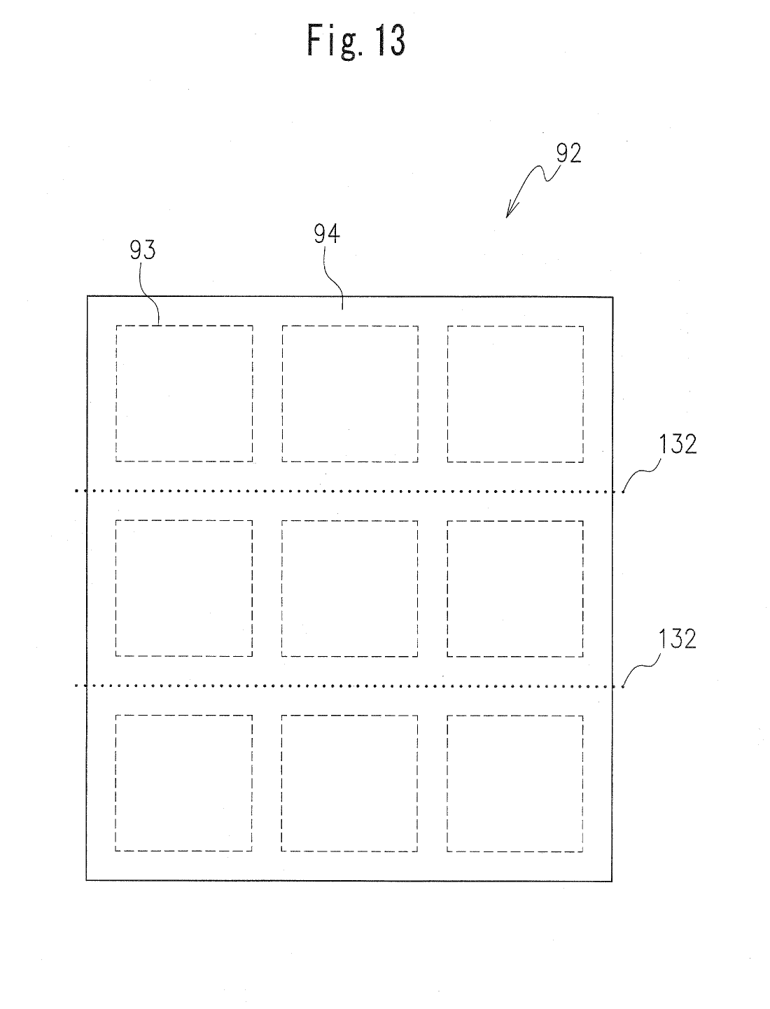

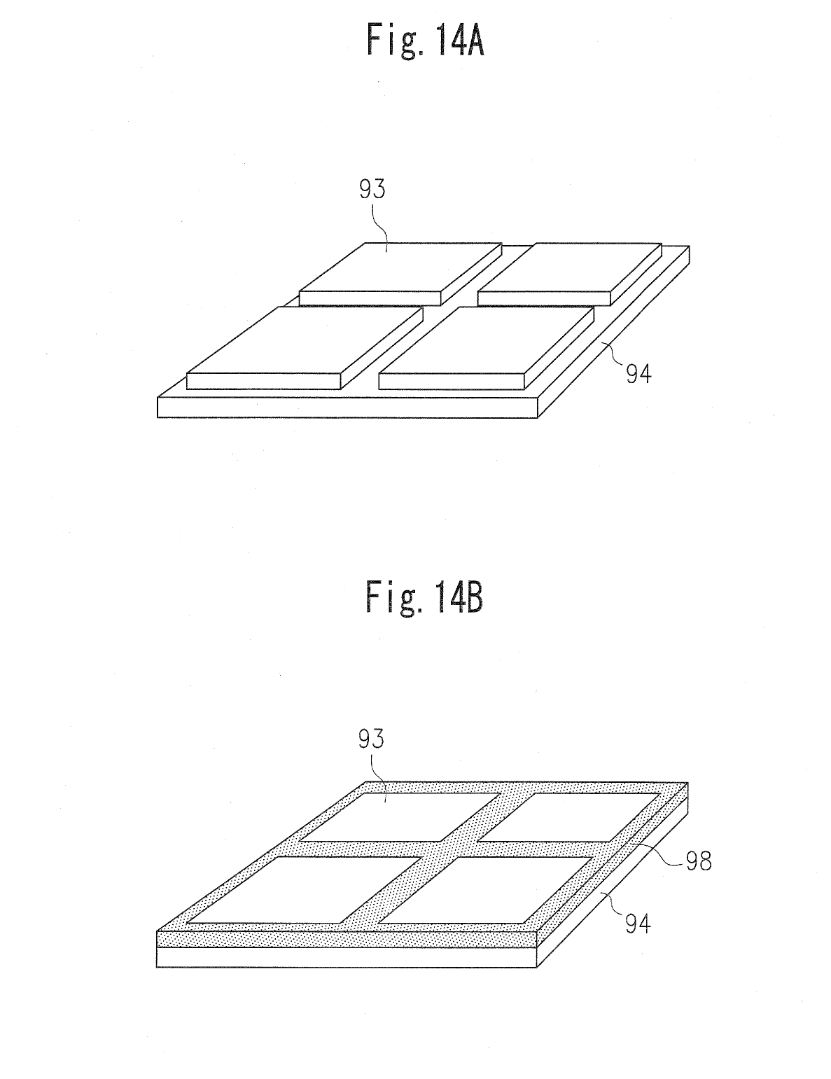

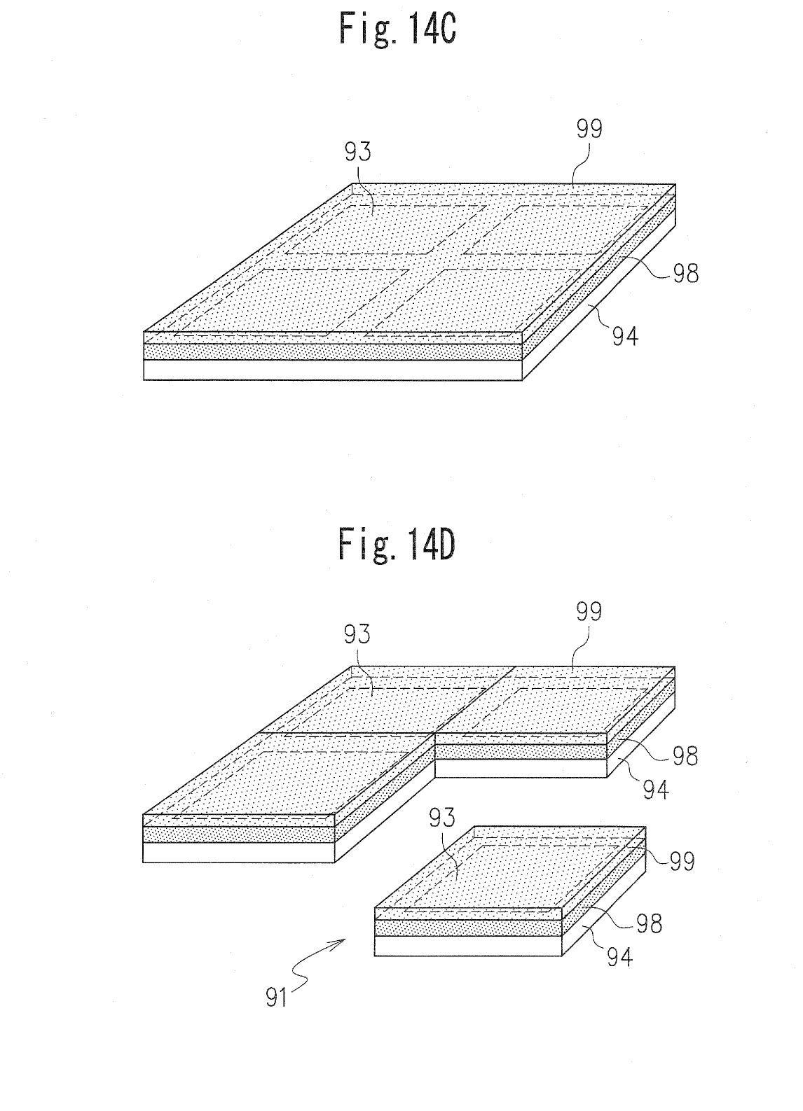

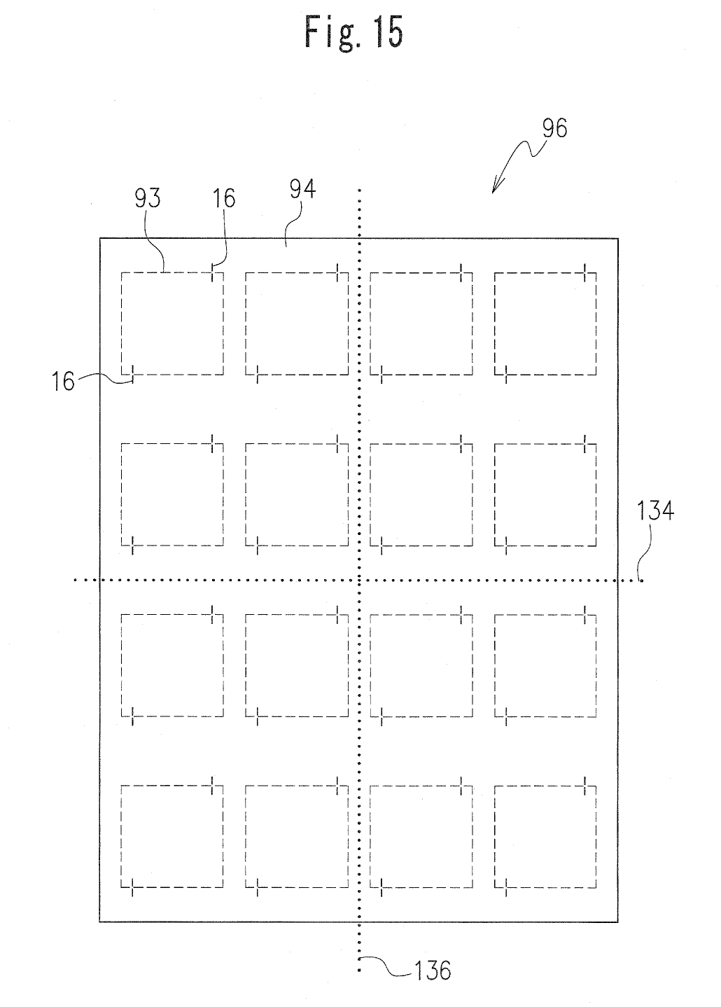

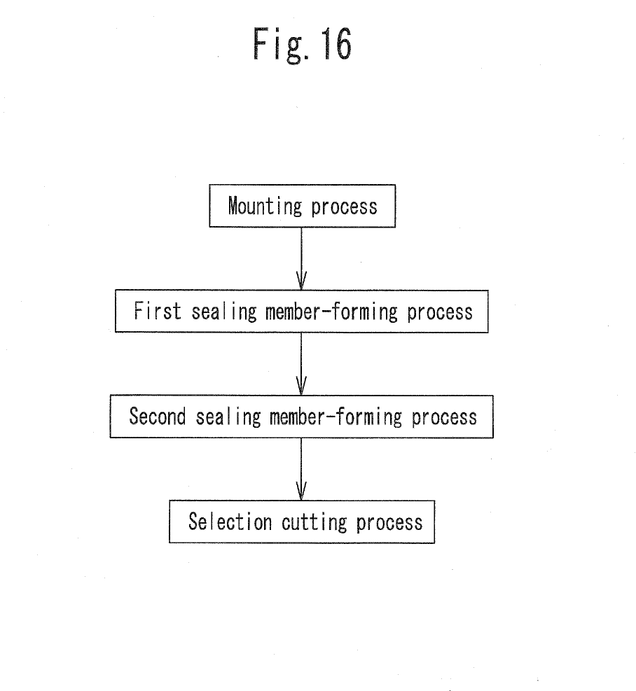

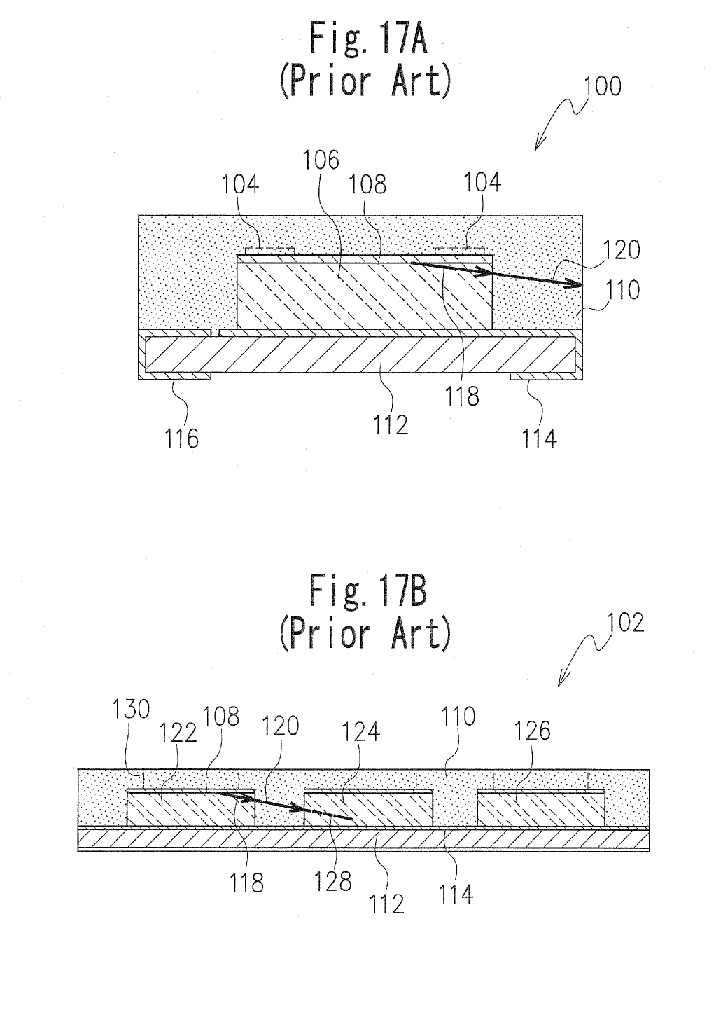

FIG. 5A is a sectional view taken along a line A-A in FIG. 7.

FIG. 8B is a sectional view taken along a line B-B in FIG. 7.

FIG. 9 is a plan view showing an LED according to a fourth embodiment of the present invention.

FIG. 10A is a sectional view taken along a line A-A in FIG. 9.

FIG. 10B is a sectional view taken along a line B-B in FIG. 9.

FIG. 11A is a sectional view explaining improved effect of emission efficiency of an LED according to the present invention.

FIG. 11B is a sectional view explaining improved effect of emission efficiency of an LED according to the present invention.

FIG. 12 is a plan view explaining a first production method of an LED according to the present invention.

FIG. 13 is a plan view explaining a second production method of an LED according to the present invention.

FIGS. 14A to 14D are perspective views showing specific processes in a production method of an LED according to the present invention.

FIG. 15 is a plan view explaining a third production method of an LED according to the present invention.

FIG. 16 is a process diagram providing a general explanation of a production method of an LED according to the present invention.

FIG. 17A is a sectional view showing a conventional LED.

FIG. 17B is a sectional view similar to that of FIG. 17A showing a conventional LED including a plurality of LED elements.

### DETAILED DESCRIPTION OF THE PREFERRED EMBODIMENTS

Preferred embodiments of the present invention will be explained in detail hereinafter, with reference to the accompanying drawings.

### First Embodiment

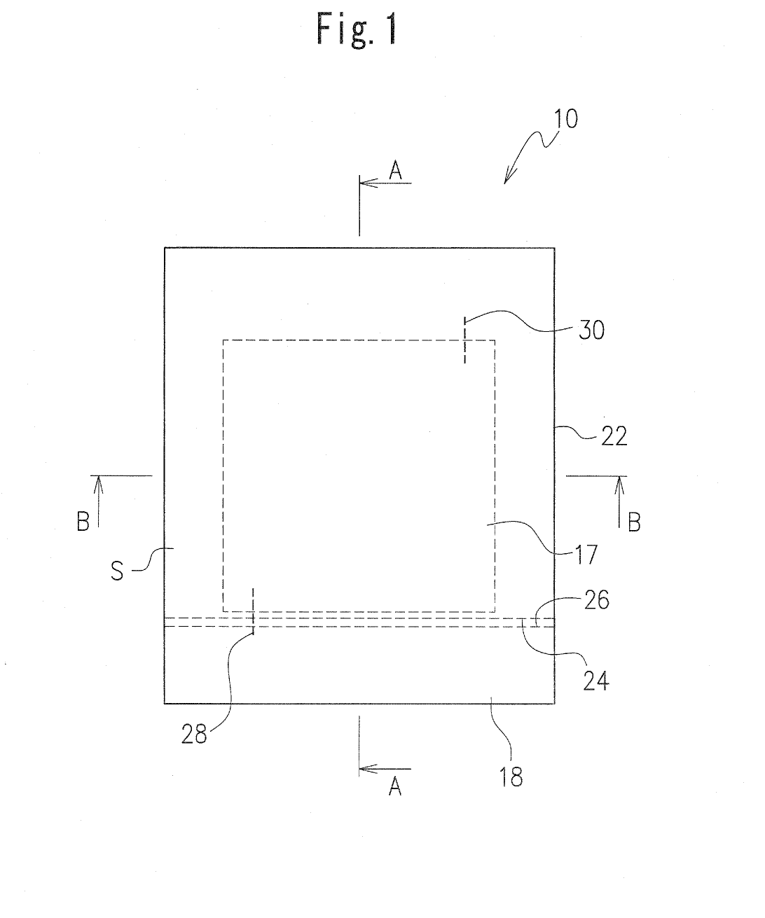

FIGS. 1, 2A, 2B and 3 illustrate an LED according to a first embodiment of the present invention.

The LED 10 in the first embodiment includes a board or printed circuit board 22 provided with electrodes 24 and 26, with at least one LED element 17 mounted on the board or printed circuit board 22 and electrically connected to the electrodes 24 and 26. Here, for example, an LED element is directly mounted on the electrode 24 (see FIGS. 1, 2A, 2B and 3). The printed circuit board 22 may be made of a resin, for example, and in the first embodiment has a rectangular shape and a certain size, and an outline of the LED element 17 here has a rectangular shape smaller than that of the printed circuit board 22 (see FIG. 1). The LED element 17 is disposed at a generally central portion of the printed circuit board 22, and therefore a space S is defined around side surfaces of the LED element 17 on an upper surface of the printed circuit board 22 (see FIG. 1).

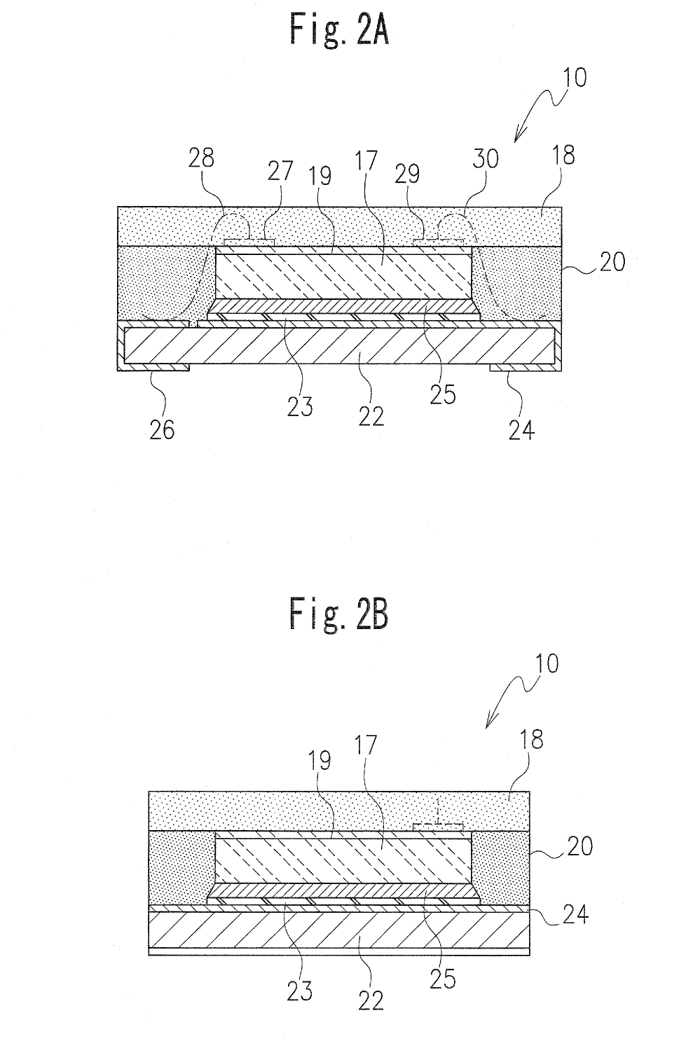

As shown in FIG. 2A, the LED element 17 includes, for example, at an upper surface thereof cathode and anode electrodes 27 and 29 disposed with a space between the electrodes 27 and 29. The electrodes 27 and 29 of the LED element 17 are electrically connected through bonding wires 28 and 30 to the electrodes 26 and 24 of the printed circuit board 22 (wire bonding system) (see FIG. 2A). Instead of using bonding wires, flip-chip bonding system using bumps may be used.

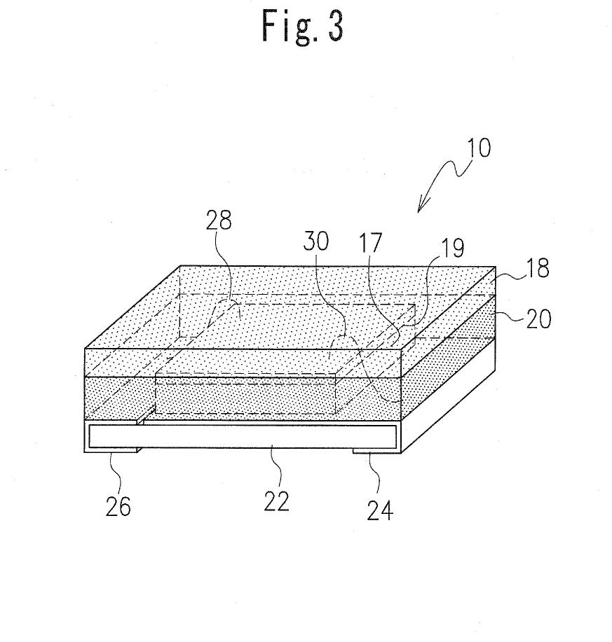

As shown in FIGS. 2A, 2B and 3, the LED element 17 has, for example, at an upper portion thereof a junction 19 which is an emission surface.

A reflection surface or plated portion 23 of silver or the like having high reflectivity is applied at least a position on the printed circuit board where the LED element 17 is mounted. Here, such a reflection surface or plated portion that reflects light emitted downwards from the junction, but the reflection surface may be formed directly on the circuit board when the LED element is directly mounted on the circuit board. The LED element 17 is adhered on the circuit board by a light-transmitting adhesive 25. In other words, the light-transmitting adhesive paste 25 is disposed between the lower surface of the LED element 17 and the reflection surface or the plated portion 23 provided on the electrode 24 (see FIGS. 2A and 2B).

The side surfaces of the LED element 17 are covered by a first sealing member 20, which has a light reflectivity or/and light-blocking property, and an upper surface of the LED element adjacent to the junction 19, which is the emission surface, is covered by a second sealing member 18 which transmits light (see FIG. 2A in particular). More specifically, as shown in FIGS. 2A and 2B, an upper surface of the first sealing member 20 is disposed to have substantially a same height as the LED element 17. The second sealing member 18 is disposed on a substantially flat surface composed of the upper surface of the LED element 17 and the upper surface of the first sealing member 20.

It is preferable that the first sealing member 20 is made of a white-type resin with a high reflectivity and the second sealing member 18 is made of a resin with a light-transmitting property or a transparent resin. It should be noted that a reflection surface with high reflectivity is preferably provided on a contact surface between the first sealing member 20 and side surfaces of the LED element 17.

In addition to the aforementioned structure, a filler of high thermal-conductivity may, for example, be contained in the first sealing member 20. If the filler is contained in the first sealing member 20, because the first sealing member 20 is closely fitted to the LED element 17, it is possible to improve the thermal-release property of the LED element 17. In addition, because the side surface of the LED element 17 is sealed by only the first sealing member 20, it is possible to achieve overall miniaturization of the LED.

To further enhance the reflectance coefficient of the first sealing member 20, a material with a high reflectance coefficient and configured to diffuse and reflect light emitted from the LED element 17 in all directions may be mixed in to the white-type resin. A white-type ceramic, a metal such as aluminum, silver or the like with a roughened surface, or plating or the like with a roughened surface may be used as a material to enhance the reflectance coefficient of the emitted light.

Improved effect of emission efficiency of the LED with the above-mentioned structure will be explained hereinafter, with reference to FIGS. 11A and 11B.

The anode and cathode electrodes 27, 29, and the bonding wires 28, 30, which are shown in FIG. 2A are omitted in FIG. 2B.

FIG. 3 is a perspective view showing the first embodiment of the LED according to the present invention. In FIG. 3, the same reference numbers are attached to parts which are the same as those shown in FIGS. 2A and 2B illustrating the first embodiment.

It should be noted that in the embodiments mentioned below, the electrodes 27, 29 of the LED element 17, the plated portion 23 of high reflectance coefficient and the conductive paste 25 are omitted.

### Second Embodiment

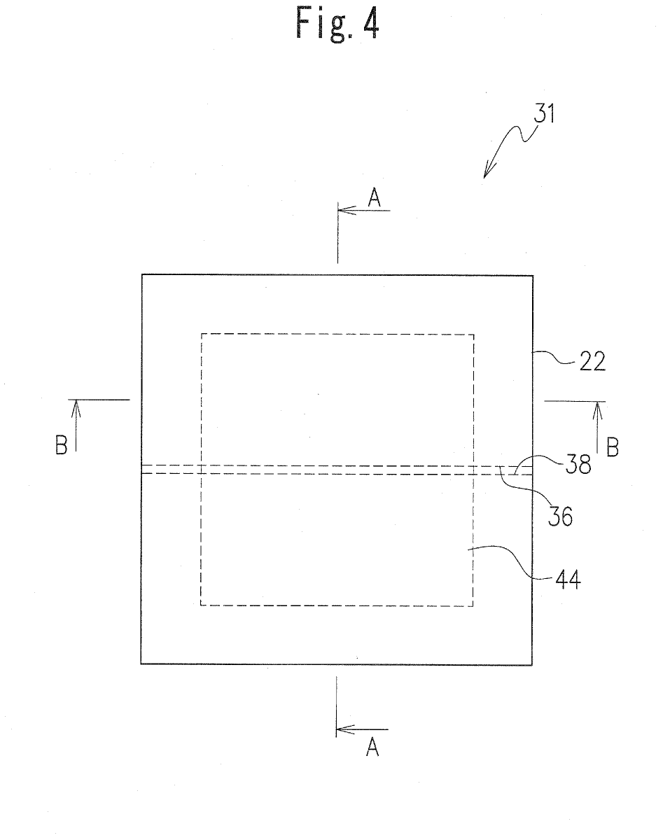

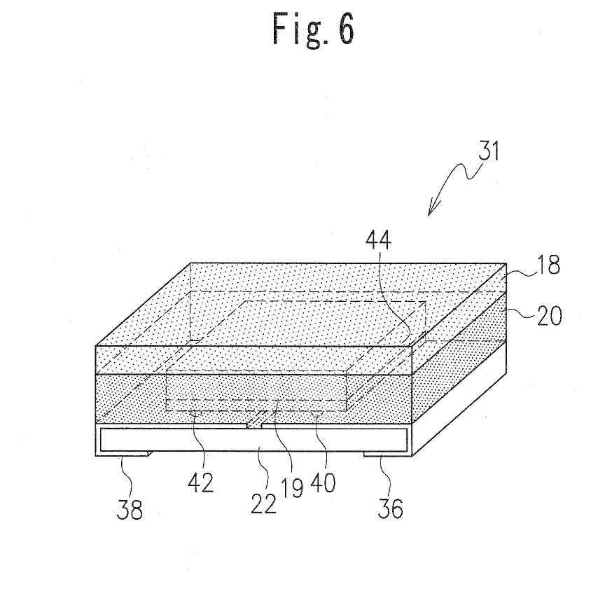

FIGS. 4, 5A, 5B and 6 illustrate an LED according to a second embodiment of the present invention. In the second embodiment, the same reference numbers are attached to parts which are the same as those in the first embodiment.

In the LED 31 according to the second embodiment, an LED element 44 is mounted on the printed circuit board 22 and electrically connected to electrodes 36 and 38 provided on the printed circuit board 22 by bumps 40 without using bonding wires (flip-chip system). Therefore, the LED in the second embodiment may be formed to have a size smaller than that according to the first embodiment. In a top plan view, outlines of the first sealing member 20, the second sealing member 18, and the printed circuit board are substantially same, and these configurations make it possible to shield lateral light from the LED element effectively, even as a smaller-sized LED.

Also, in the second embodiment, because it is not necessary to provide bonding wire portions to connect wires on the electrodes in addition to a lower surface-mounting portion of the LED element when performing electrical connection of the LED element and the electrodes, as described in the first embodiment, the printed circuit board 22 in the second embodiment can have a size smaller than that in the first embodiment.

Also, in the second embodiment, because the flip-chip system is used, the junction which is the emission surface of the LED element 44 is disposed at a lower portion of the LED element 44, in other words, at a position close to the upper surface of the printed circuit board 22 as shown in FIGS. 5A and 5B. In the LED 31 in the second embodiment, the side surface of the LED element 44 is surrounded by the first sealing member 20, and the upper surfaces of the LED element 44 and the first sealing member 20 are covered by the second sealing member 18, in the same way as in the LED 10 of the first embodiment.

### Third Embodiment

FIGS. 7, 8A and 8B illustrate an LED according to a third embodiment of the present invention.

In the LED 50 in the third embodiment, three LED elements 52, 54 and 66 are mounted on the printed circuit board 22, as shown in FIGS. 7 and 8B. The LED elements 52, 54 and 56 are electrically connected through wires 16 to electrodes 64 and 66 provided on the printed circuit board 22 (see FIGS. 8A and 8B). A first sealing member 62 is disposed to surround side surfaces of each of the LED elements 52, 54 and 56, and a second sealing member 60 is disposed to cover a substantially flat surface composed of the upper surfaces of the LED elements 52, 54 and 56 and the first sealing member 62.

### Fourth Embodiment

FIGS. 9, 10A an 10B illustrate an LED according to a fourth embodiment of the present invention.

In the LED 70 in the fourth embodiment, three LED elements 72, 74 and 76 are mounted on the printed circuit board 22, in the same way as in the LED 50 of the third embodiment, the flip-chip system is used as a mounting method, in the same way as in the second embodiment, and electrodes (not shown) of each of the LED elements 72, 74 and 76 are electrically connected through bumps 78 to the electrodes 64 provided on the printed circuit board 22.

Therefore, in the fourth embodiment, the junction 19 of each of the LED elements 72, 74 and 76 is disposed to be positioned in a lower portion of the LED element (see FIGS. 10A and 10B). In the fourth embodiment, the first sealing member 62 is disposed to surround the side surface of each of the LED elements 72, 74 and 76, and the second sealing member 60 is disposed to cover the upper surfaces of the LED elements 72, 74 and 76 and the first sealing member 62, in the same way as in the third embodiment.

FIGS. 11A and 11B illustrate the improved effect of emission efficiency of the LED according to the present invention.

FIG. 11A illustrates a case where one LED element 17 is mounted and FIG. 11B illustrates a case where three LED elements 52, 54 and 56 are mounted. Moreover, FIG. 11A and FIG. 11B illustrate examples of light emitted laterally to the right from the junction of the LED element 17 and 52.

In FIG. 11A, light 80 is laterally emitted light from the junction 19 of the LED element 17, and enters the first sealing member 20 having a high diffusion and reflectance coefficient. The light 86 is an example of light in a case without the first sealing member 20, just like the light 120 shown in a conventional LED of FIG. 17A. It is preferable that most of light is reflected on the first sealing member 20, a part of light may enter the first sealing member 20 and be diffused and reflected like eventually upward lights 82 and 84.

In this way, the LED according to the present invention can use most of the light emitted from the junction of the LED element as light directed upward, thereby enabling sufficient improvement of emission efficiency in the upward direction.

FIG. 11B illustrates a case in which emitted light is written onto FIG. 8B showing the LED 50 according to the third embodiment of the present invention.

The light 88 is an example of light in a case without the first sealing member 62, just like the light 120 shown in a conventional LED of FIG. 17B. It is preferable that most of light is reflected on the first sealing member 62, a part of light may enter the first sealing member 62 and be diffused and reflected like eventually upward lights 82 and 84.

In this way, the LED according to the present invention causes most of the light emitted from the junction in a lateral direction to be diffused without being absorbed in the adjacent LED element and emitted upwardly, thereby enabling sufficient improvement of emission efficiency in the upward direction. In a top plan view, outlines of the first sealing member 62, the second sealing member 60, and the printed circuit board 22 are substantially same, and these configurations make it possible to shield lateral light from the LED elements effectively, even as a smaller-sized LED.

FIG. 12 illustrates a first method for producing an LED 90 according to the present invention.

In FIG. 12, LED elements 93 are mounted on a board aggregate 94 in a manner such that three LED elements are arranged in a vertical direction and three LED elements are arranged in a horizontal direction. Each of the LED elements 93 is electrically connected to electrodes (not shown) provided on the board aggregate 94 through wires 16, by use of a wire bonding system.

FIG. 13 illustrates a second method for producing an LED 92 according to the present invention.

In the second production method, the LED elements 93 are mounted on the board aggregate 94 in a manner such that four LED elements are arranged in a vertical direction and four LED elements are arranged in a horizontal direction by use of a flip-chip system.

FIG. 15 illustrates a third method for producing the LED 90 according to the present invention.

In the third production method, the LED elements 93 are mounted on the board aggregate 94 in a manner such that four LED elements are arranged in a vertical direction and four LED elements are arranged in a horizontal direction by use of a wire bonding system.

Meanwhile, in the embodiment shown in each of FIGS. 12, 13 and 15, a first sealing member is disposed between the adjacent LED elements, and a second sealing member is disposed on upper surfaces of the first sealing member and the LED elements. Consequently, the obtained LED includes a board, a plurality of LED elements mounted on the board, a first sealing member disposed between the adjacent LED elements and a second sealing member disposed to cover the first sealing member and the LED elements.

FIG. 16 illustrates a schematic method for producing an LED according to the present invention, and FIGS. 14A and 14B illustrate a concrete method for producing an LED according to the present invention.

The production method for the LED according to the present invention includes a mounting process, a first sealing member-forming process, a second sealing member-forming process and a selection cutting process, as shown in FIG. 16.

In the mounting process, the plurality of LED elements 93 are mounted on the board aggregate 94. Nine LED elements 93 are mounted 3×3 in FIGS. 12 and 13, four LED elements 93 are mounted 2×2 in FIGS. 14 to 14D, and sixteen LED elements 93 are mounted 4×4 in FIG. 15. A wire bonding system or flip-chip system may be used as the mounting method. Of course, any further method may be used.

FIG. 14A illustrates a state in which the LED elements 93 are mounted on the board aggregate 94.

In the first sealing member-forming process, a space between the plurality of LED elements 93 mounted on the board aggregate 94 is filled with a first sealing member 98 which has a diffusion and reflectivity property and is configured to shield and reflect light other than light emitted from the upper surfaces of the LED elements in such a manner that an upper surface of the first sealing member is at the same level as an upper surface of each of the LED elements 93.

FIG. 14B illustrates an LED assembly in which the first sealing member-forming process has been completed, and an amount of the first sealing member 98 has been adjusted so that the upper surface of the first sealing member and the upper surface of each of the LED elements 93 are at the same level.

In the second sealing member-forming, process, the upper surfaces of the first sealing member 98 and the plurality of LED elements 93 are covered by a light-transmitting second sealing member 99.

FIG. 14C illustrates an LED assembly in which the second sealing member-forming process has been completed.

In the selection cutting process, the LED assembly is cut into single LEDs. Here, it should be noted that the number of the LED elements installed in the LED is decided in the selection cutting process. As shown in FIGS. 12 and 13, when each of the LEDs 90 and 92, that is to say, the board aggregate, the first sealing member and the second sealing member are cut along two horizontally extending parallel dotted lines 130, a plurality of LEDs in each of which three LED elements are arranged in a horizontal direction can be obtained. Also, as shown in FIG. 15, when the LED 96, that is to say, the board aggregate, the first sealing member and the second sealing member are cut along horizontal and vertical dotted lines 134 and 136, LEDs in each of which four LED elements are arranged 2×2 can be acquired. Moreover, as shown in FIG. 14D, when one LED is cut out, an LED 91 in which one LED element is mounted can be obtained.

In an actual LED assembly, because a plurality of LEDs are mounted, it is necessary to cut in both vertical and horizontal directions of the LED assembly, even if the LED assembly has a structure in which three LED elements are mounted.

In the production method according to the present invention, the number of the LED elements mounted in one LED can be decided in the selection cutting process. That is to say, even if the number of LED elements to be mounted differs, it is possible to undertake the mounting process, the first sealing member-forming process, and the second sealing member-forming process in common. Accordingly, it is possible to prepare and stock, and achieve the significant advantageous effect of a reduced production cost.

It should be noted that an LED on which a plurality of LED elements are mounted is effective in making white light by mixing emission light of the three primary colors emitted from Red, Green and Blue LED elements, and that brightness of the LED can be effectively increased by increasing the number of LED elements.

As mentioned above, although the preferred embodiments of the present invention have been described, it should be noted that the present invention is not limited to these embodiments, and that various modifications and changes can be made to the embodiments.

For example, if a resin having a high diffusion and reflectance coefficient is disposed to cover the side surfaces of the LED element, it is possible to efficiently reflect light emitted from the junction of the LED element horizontally. In this case, because the side surfaces of the LED element are covered by the resin with high diffusion and reflectivity effects, miniaturization of the LED package can be achieved.

In addition, even if a plurality of LED elements are gathered in portion of the board with a small area, because the absorption of light by the adjacent LED element is reduced by the first sealing member having a high diffusion and reflectance coefficient, it is possible to improve emission efficiency of the LED.

Moreover, because the first sealing member is closely fitted to the LED element, if a material having high thermal conductivity is mixed into the first sealing member, the heat-release property of the LED can be increased.

Furthermore, in the production method according to the present invention, because it is possible to produce an assembly of large size by the same process regardless of the number of LED elements, and produce LEDs having different numbers of LED elements only by a change in the cutting process, there is an advantageous effect that inexpensive LEDs can be provided.

What is claimed is:

1. A light-emitting diode, comprising:
a printed circuit board including at least a pair of electrodes;
a plurality of light-emitting diode elements each including a junction and mounted on the printed circuit board, and the light-emitting diode elements electrically connected to the electrodes, respectively;
a first sealing member disposed on the printed circuit board to cover side surfaces of the light-emitting diode elements and having a substantially same height as the light-emitting diode elements; and
a second sealing member disposed to cover the upper surfaces of the light-emitting diode elements and the upper surface of the first sealing member,
the first sealing member being configured to reflect emitted laterally from the junctions of the light-emitting diode elements.
the second sealing member being configured to transmit light emitted from the junctions of the light-emitting diode elements.

2. The light-emitting diode according to claim 1,
wherein each of the light-emitting diode elements is mounted on the printed circuit board through a light-transmitting adhesive,
wherein the printed circuit board includes a reflection surface provided at least positions where the light-emitting diode elements are mounted.

3. The light-emitting diode according to claim 1,
wherein each of the light-emitting diode elements is mounted on one of the pair of electrodes through a light-transmitting adhesive,
wherein the one electrode includes a reflection surface provided at positions where the light-emitting diode elements are mounted.

4. The light-emitting diode according to claim 1,
wherein a filler having a high thermal conductivity is contained in the first sealing member.

5. The light-emitting diode according to claim 1,
wherein the first sealing member comprises a white-type resin including at least one selected from among a white-type ceramic, a metal with a roughened surface, and a plating with a roughened surface.

6. A method for producing a light-emitting diode, comprising:
a mounting process to mount a plurality of light-emitting diode elements on a board aggregate including a plurality of separable boards;
a first sealing member-forming process to form a first sealing member which shields and reflects light between adjacent light-emitting diode elements in such a manner that an upper surface of the first sealing member is at the same level as upper surfaces of the light-emitting diode elements;
a second sealing member-forming process to form a second sealing member which is light-transmitting and seals the upper surface of the first sealing member and the upper surfaces of the light-emitting diode elements; and
a cutting process to selectively cut the board aggregate, the first sealing member and the second sealing member to form a light-emitting diode including a board, at least one light-emitting diode element mounted on the board, a first sealing member disposed to surround the light-emitting diode element and a second sealing member disposed to cover the first sealing member and the light-emitting diode element.

7. The method according to claim 6,
wherein the first sealing member-forming process contains a process to include a filler having high thermal conductivity in the first sealing member.

8. The method according to claim 6,
wherein the first sealing member-forming process contains a process in which a white-type resin to form the first sealing member is prepared and has mixed within it any one of a white-type ceramic, a metal such as aluminum, silver or the like with a roughened surface, and a plating or the like with a roughened surface.

9. The method according to claim 6,
wherein the cutting process includes a process to cut the board aggregate, the first sealing member and the second sealing member to form individual light-emitting diodes,
each of the light-emitting diodes including a board, a plurality of light-emitting diode elements mounted on the board, a first sealing member disposed to surround the light-emitting diode elements and a second sealing member disposed to cover the first sealing member and the light-emitting diode elements.
